(19) United States
(12) Patent Application Publication
(10) Pub. No.: US 2024/0155778 A1
(43) Pub. Date: May 9, 2024

(54) WIRING SUBSTRATE

(71) Applicant: SHINKO ELECTRIC INDUSTRIES CO., LTD., Nagano-shi (JP)

(72) Inventor: Akihiro Takeuchi, Nagano (JP)

(21) Appl. No.: 18/502,605

(22) Filed: Nov. 6, 2023

(30) Foreign Application Priority Data
Nov. 9, 2022 (JP) 2022-179754

(51) Int. Cl. H05K 3/46

(52) U.S. Cl. CPC H05K 3/4688; H05K 2201/0212; H05K 2203/0369

(57) ABSTRACT

A wiring substrate includes a metal layer, a resin layer, and a wiring structure. The resin layer is laminated on the metal layer. The wiring structure includes a wiring layer and an insulating layer that are laminated on the resin layer, and in which the wiring layer is located by being brought into contact with the resin layer.

### CROSS-REFERENCE TO RELATED APPLICATION

This application is based upon and claims the benefit of priority of the prior Japanese Patent Application No. 2022-179754, filed on Nov. 9, 2022, the entire contents of which are incorporated herein by reference.

### FIELD

The embodiment discussed herein is related to a wiring substrate, a method of manufacturing a wiring substrate, and a method of manufacturing a semiconductor device.

### BACKGROUND

With a reduction in thickness of the semiconductor devices, development of thinner wiring substrate having mounted thereon on a semiconductor chip to form a semiconductor device is facilitated. As the wiring substrate becomes thinner, stiffness of the wiring substrate is decreased.

In contrast, from a standpoint of ensuring the stiffness, there has been proposed a wiring substrate constructed such that a wiring structure is laminated on a metal layer (thin foil) that is thinner than a carrier plate (thick foil) is pasted in a strippable manner on the carrier plate included in a metal foil with carrier (see Japanese Laid-open Patent Publication No. 2016-33967).

However, with the wiring substrate in which the wiring structure is laminated on the metal layer that is included in the metal foil with carrier, it is not considered to suppress damage caused by removal of the metal layer.

That is, with the wiring substrate in which the wiring structure is laminated on the metal layer that is included in the metal foil with carrier, after having performed a process of mounting the semiconductor chip, a process of forming a encapsulating resin, and the like, the wiring structure is separated from the carrier plate by stripping the metal layer (thin foil) from a carrier plate. When the wiring structure is separated from the carrier plate, the metal layer remains on the lower surface of the wiring structure. In order to expose the wiring layer that is located on the lower surface of the wiring structure, the metal layer remaining on the lower surface of the wiring structure is removed by an etching process performed by using an etching solution in the end. At this time, the etching solution dissolves the wiring layer disposed on the lower surface of the wiring structure together with the metal layer, and as a result, the wiring structure may possibly be damaged.

### SUMMARY

According to an aspect of an embodiment, a wiring substrate includes a metal layer; a resin layer that is laminated on the metal layer; and a wiring structure that includes a wiring layer and an insulating layer that are laminated on the resin layer, and in which the wiring layer is located by being brought into contact with the resin layer.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a plan view illustrating a configuration of a wiring substrate according to an embodiment;

FIG. 2 is a cross-sectional view illustrating a configuration of a wiring substrate according to the embodiment;

FIG. 3 is a flowchart illustrating one example of the flow of a method of manufacturing the wiring substrate according to the embodiment;

FIG. 4 is a specific example illustrating a supporting body preparation step;

FIG. 5 is a diagram illustrating a specific example of a wiring layer forming step;

FIG. 6 is a diagram illustrating a specific example of an insulating layer forming step;

FIG. 7 is a diagram illustrating a specific example of an opening portion forming step;

FIG. 8 is a diagram illustrating a specific example of a seed layer forming step;

FIG. 9 is a diagram illustrating a specific example of a resist layer forming step;

FIG. 10 is a diagram illustrating a specific example of an electrolytic plating step;

FIG. 11 is a diagram illustrating a specific example of a resist layer removal step;

FIG. 12 is a diagram illustrating a specific example of an etching step;

FIG. 13 is a diagram illustrating a specific example of a solder resist layer forming step;

FIG. 14 is a diagram illustrating a specific example of a separated wiring substrate;

FIG. 15 is a flowchart illustrating one example of the flow of a method of manufacturing a semiconductor device according to the embodiment;

FIG. 16 is a diagram illustrating a specific example of a semiconductor chip mounting step;

FIG. 17 is a diagram illustrating a specific example of a mold step;

FIG. 18 is a diagram illustrating a specific example of a metal layer removal step;

FIG. 19 is a diagram illustrating a specific example of an opening portion forming step;

FIG. 20 is a diagram illustrating a structure of the semiconductor device;

FIG. 21 is a diagram illustrating a specific example of a resin layer removal step; and

FIG. 22 is a diagram illustrating the semiconductor device.

### DESCRIPTION OF EMBODIMENT

Preferred embodiment of a wiring substrate, a method of manufacturing a wiring substrate, and a method of manufacturing a semiconductor device disclosed in the present invention will be described in detail below with reference to the accompanying drawings. In addition, the disclosed technology is not limited by the embodiment.

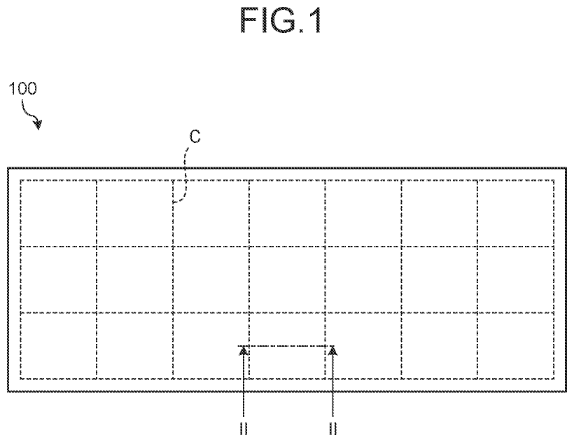

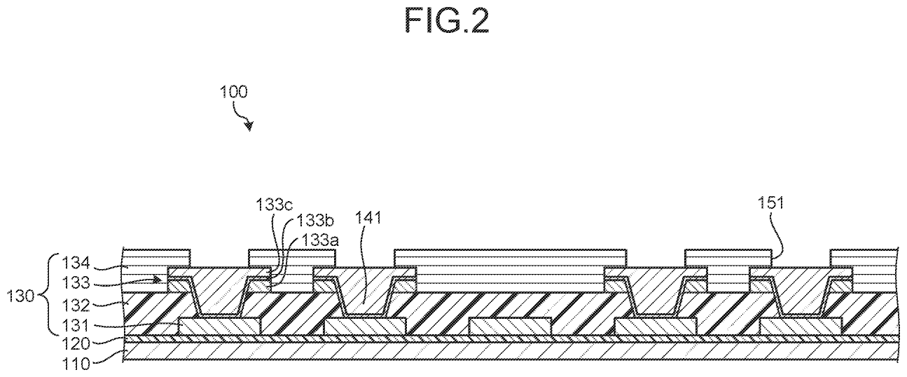

FIG. 1 is a plan view illustrating a configuration of a wiring substrate 100 according to an embodiment. FIG. 2 is a partial cross-sectional view illustrating the configuration of the wiring substrate 100 according to the embodiment. FIG. 2 indicates a partial cross section taken along line II-II illustrated in FIG. 1.

As illustrated in FIG. 1, the wiring substrate 100 is a sheet-shaped wiring substrate that includes a plurality of areas surrounded by broken lines C. The wiring substrate 100 is able to use as a substrate of a semiconductor package (semiconductor device) on which, for example, a semiconductor chip is mounted. In other words, after a process of mounting the semiconductor chip, a process of encapsulating a resin, and the like have been performed on the wiring substrate 100, a metal layer that will be described later is removed and then the wiring substrate 100 is cut along the broken lines C in the end, so that a plurality of diced semiconductor devices are obtained. Furthermore, the number of the plurality of areas surrounded by the broken lines C is not limited to the number of the areas illustrated in FIG. 1.

As illustrated in FIG. 2, the wiring substrate 100 has a laminated structure, and includes a metal layer 110, a resin layer 120, and a wiring structure 130. In the following, as illustrated in FIG. 2, a description will be made on the assumption that a solder resist layer 134, which will be described later, is an uppermost layer, and the metal layer 110 is a lowermost layer that are included in the wiring structure 130; however, the wiring substrate 100 may be used by, for example, vertically inverting the surfaces, or may be used in an arbitrary orientation.

The metal layer 110 is formed by using, for example, copper or a copper alloy. The metal layer 110 has a function as a base layer that supports the wiring structure 130 and that also reinforces the wiring substrate 100. The metal layer 110 is finally removed by an etching process performed by using an etching solution in order to allow the wiring layer that is located on the lower surface of the wiring structure 130 to be exposed. The thickness of the metal layer 110 may be set to, for example, about 5 to 50 μm.

The resin layer 120 is laminated on the metal layer 110. The resin layer 120 is formed by using an insulating resin having etching resistance with respect to the etching solution that is used to remove the metal layer 110. Such an insulating resin used may be a thermosetting insulating resin that becomes hardened by heat, that is, for example, a thermosetting epoxy resin, a thermosetting polyimide resin, or the like. The resin layer 120 is formed by using an insulating resin that does not include a reinforcement material, such as a glass woven fabric. The resin layer 120 may be formed by using the same insulating resin as an insulating resin that is used for the insulating layer (an insulating layer 132 that will be described later) that is included in the wiring structure 130. The thickness of the resin layer 120 is thinner than that of the metal layer 110. The thickness of the resin layer 120 may be set to, for example, about 3 to 30 μm. Furthermore, the thickness of the resin layer 120 may be thinner than that of a wiring layer 131 that will be described later. Moreover, the thickness of the resin layer 120 may be thinner than that of the insulating layer 132 and the solder resist layer 134 that will be described later.

The wiring structure 130 is a multi-layer wiring structure in which an insulating layer having an insulating and a wiring layer having a conductive property are laminated. That is, the wiring structure 130 includes the wiring layer 131, the insulating layer 132, a wiring layer 133, and the solder resist layer 134.

The wiring layer 131 is a layer that is formed on the resin layer 120 and that includes a pad and a wiring pattern. The wiring layer 131 is located on the lower surface of the wiring structure 130 and forms the lowermost layer of the wiring structure 130. The wiring layer 131 is formed by using, for example, copper or a copper alloy. The wiring layer 131 is formed on the resin layer 120 by using, for example, a subtractive method. The thickness of the wiring layer 131 may be set to, for example, about 5 to 50 μm.

The insulating layer 132 is a layer that is formed on the resin layer 120 so as to cover the wiring layer 131. The insulating layer 132 is formed by impregnating, for example, a reinforcement material, such as a glass woven fabric, with an insulating resin, such as an epoxy resin. The reinforcement material used may be, in addition to the glass woven fabric, a glass non-woven fabric, an aramid woven fabric, an aramid non-woven fabric, or the like. Furthermore, the insulating resin used may be, in addition to the epoxy resin, a polyimide resin, or the like. The thickness of the insulating layer 132 between the upper surface of the wiring layer 131 and the upper surface of the insulating layer 132 may be set to, for example, about 10 to 30 μm.

The wiring layer 133 is a layer that is formed on the insulating layer 132 and that includes a pad and a wiring pattern. The wiring pattern of the wiring layer 133 is electrically connected, as appropriate, to the wiring pattern of the wiring layer 131 by vias 141 each of which passes through the insulating layer 132. At a position in which each of the vias 141 is formed, the wiring layer 133 is constituted by a metal foil layer 133a, a seed layer 133b that is formed on the metal foil layer 133a by electroless plating, and an electrolytic plating layer 133c that is formed on the seed layer 133b by electrolytic plating. Each of the vias 141 is formed such that the electrolytic plating is filled on the seed layer 133b inside the opening portion disposed in the insulating layer 132. The wiring layer 133 and each of the vias 141 are formed by using, for example, a semi-additive method. The wiring layer 133 is formed by using, for example, copper or a copper alloy. The thickness of the wiring layer 133 may be set to, for example, about 3 to 50 μm.

In this embodiment, the wiring layer 131 disposed in the lowermost layer included in the wiring structure 130 is located by being brought into contact with the resin layer 120 that is disposed on the metal layer 110. In other words, the resin layer 120 is present between the wiring layer 131 and the metal layer 110 that are located on the lower surface of the wiring structure 130.

In this way, in the embodiment, the wiring layer 131 disposed in the lowermost layer included in the wiring structure 130 is located by being brought into contact with the resin layer 120 that is disposed on the metal layer 110, so that the lower surface of the wiring layer 131 is protected by the resin layer 120. The resin layer 120 that protects the lower surface of the wiring layer 131 is formed by using an insulating resin having etching resistance with respect to an etching solution that is used to remove the metal layer 110. As a result of this, when the metal layer 110 is finally removed by an etching process performed by using an etching solution, the resin layer 120 that is disposed on the lower surface of the wiring layer 131 functions as a protection wall with respect to the etching solution. Therefore, according to the embodiment, the etching solution does not dissolve the wiring layer 131 and it is thus possible to suppress damage of the wiring structure 130 caused by the removal of the metal layer 110.

Furthermore, in the embodiment, the resin layer 120 is formed by using the insulating resin that does not include a reinforcement material, so that it is possible to reduce the thickness of the resin layer 120 as compared to the resin layer that is formed by using an insulating resin that includes a reinforcement material. Therefore, according to the embodiment, it is possible to facilitate a reduction in the thickness of the wiring substrate 100.

Furthermore, in the embodiment, the resin layer 120 is formed by using the same insulating resin as that that is used for the insulating layer (i.e., the insulating layer 132 and the solder resist layer 134) included in the wiring structure 130, so that it is possible to easily form the resin layer 120. Therefore, according to the embodiment, it is possible to reduce a manufacturing cost of the wiring substrate 100.

Furthermore, in the embodiment, the thickness of the resin layer 120 is thinner than that of the metal layer 110, so that it is possible to further facilitate a reduction in the thickness of the wiring substrate 100 while ensuring stiffness of the wiring substrate 100.

The solder resist layer 134 is a layer that covers the wiring layer 133 disposed at the uppermost layer of the wiring structure 130 and that protects the wiring pattern of the wiring layer 133. The solder resist layer 134 is a layer constituted of, for example, a photosensitive resin, such as an acrylic resin and a polyimide resin, having an insulating, and is one of the insulating layer. Furthermore, the solder resist layer 134 may be formed by using, for example, a non-photosensitive resin, such as an epoxy resin, having an insulating. The thickness of the solder resist layer 134 between the upper surface of the wiring layer 133 and the upper surface of the solder resist layer 134 may be set to, for example, about 4 to 30 μm.

The solder resist layer 134 side included in the wiring substrate 100 is a surface on which, for example, an electronic component, such as a semiconductor chip, is mounted. At the position at which the semiconductor chip is mounted, an opening portion 151 is formed in the solder resist layer 134, and the upper surface of the wiring layer 133 is exposed from the opening portion 151. In the case where the solder resist layer 134 is formed by using the photosensitive resin, it is possible to form the opening portion 151 by performing a process of exposure and image development. In the case where the solder resist layer 134 is formed by using a non-photosensitive resin, it is possible to form the opening portion 151 by performing a process of laser beam machining. It is possible to electrically connect electrodes of the semiconductor chip to the wiring layer 133 that is exposed from the opening portion 151.

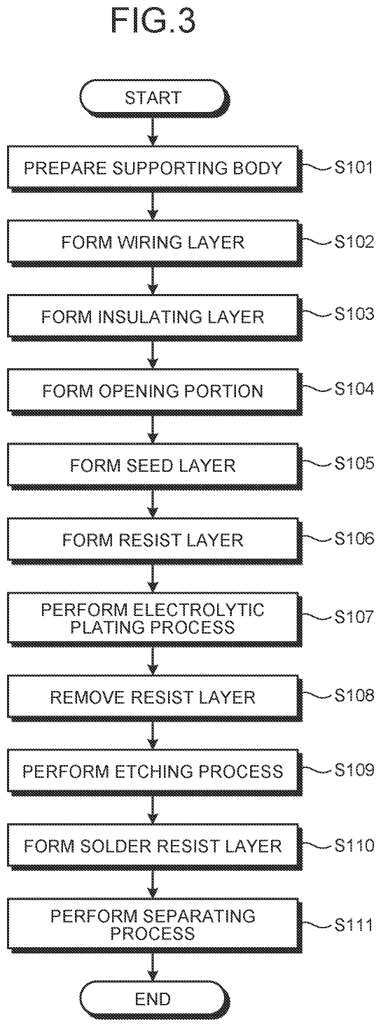

In the following, a method of manufacturing the wiring substrate 100 configured as described above will be described with reference to FIG. 3 by using specific examples. FIG. 3 is a flowchart illustrating one example of the flow of the method of manufacturing the wiring substrate 100 according to the embodiment.

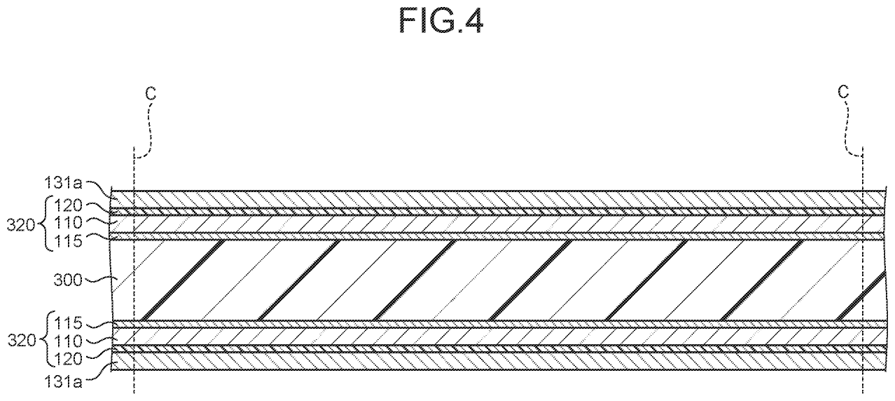

First, a supporting body 300 that serves as the base at the time of manufacturing the wiring substrate 100 is prepared (Step S101). Specifically, for example, as illustrated in FIG. 4, on the upper surface and the lower surface of the plate shaped supporting body 300, a metal foil with resin 320 and a metal foil 131a are laminated in this order starting from the supporting body 300 side. FIG. 4 is a diagram illustrating a specific example of a supporting body preparation step.

The supporting body 300 is a prepreg obtained by impregnating a reinforcement material, such as a woven fabric or a non-woven fabric made from, for example, glass fibers, aramid fibers, or the like with an insulating resin, such as an epoxy resin. The supporting body 300 is formed such that the upper surface has a flat plate shape.

The metal foil with resin 320 is a metal foil constituted by a foundation layer (thin foil) 115, the metal layer 110 that is pasted in a strippable manner on the foundation layer 115 via a release layer (not illustrated), and the resin layer 120 that is laminated on the metal layer 110. The foundation layer 115 is a layer that has the thickness of about 3 to 18 μm and that is formed by using, for example, copper or a copper alloy. The metal foil 131a is formed by using, for example, copper or a copper alloy.

The metal foil with resin 320 and the metal foil 131a that are laminated on each of the upper surface and the lower surface of the supporting body 300 are brought into close contact with the supporting body 300 by vacuum lamination and vacuum heat pressure bonding by a press working process. Furthermore, when the metal foil with resin 320 is subjected to vacuum heat pressure bonding, the supporting body 300 and the resin layer 120 become hardened due to heating and pressurization. As a result of this, it is possible to obtain the supporting body 300 in which the metal foil with resin 320 and the metal foil 131a are sequentially laminated on each of the upper surface and the lower surface.

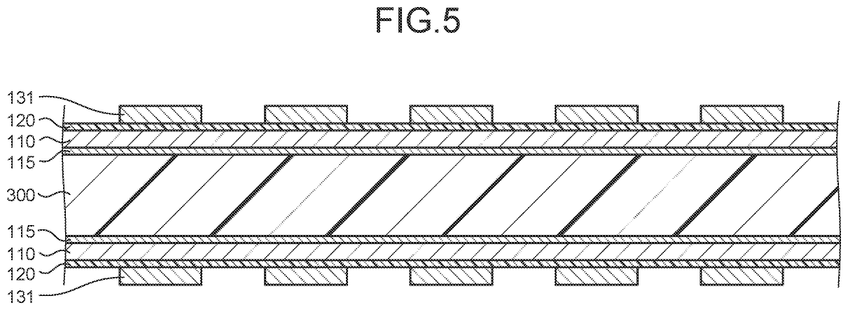

When the supporting body 300 has been prepared, the wiring structure 130 is formed by laminating the wiring layer and the insulating layer on the resin layer 120 that is included in the metal foil with resin 320. The processes performed at Steps S102 to S110 described below correspond to a forming step of the wiring structure 130. First, for example, as illustrated in FIG. 5, the wiring layer 131 is formed on the resin layer 120 (Step S102). FIG. 5 is a diagram illustrating a specific example of a wiring layer forming step. The wiring layer 131 is formed from the metal foil 131a that is laminated on the resin layer 120 by using, for example, a subtractive method. In this case, an etching resist layer is laminated on the metal foil 131a, and a process of exposure and image development is performed in accordance with a wiring pattern forming position, so that the etching resist layer having an opening at a portion other than the position at which the wiring pattern is formed is formed. Subsequently, the wiring layer 131 is formed by etching the metal foil 131a that is exposed from the opening of the etching resist layer. After this, by removing the etching resist layer, the wiring layer 131 having a desired wiring pattern is formed.

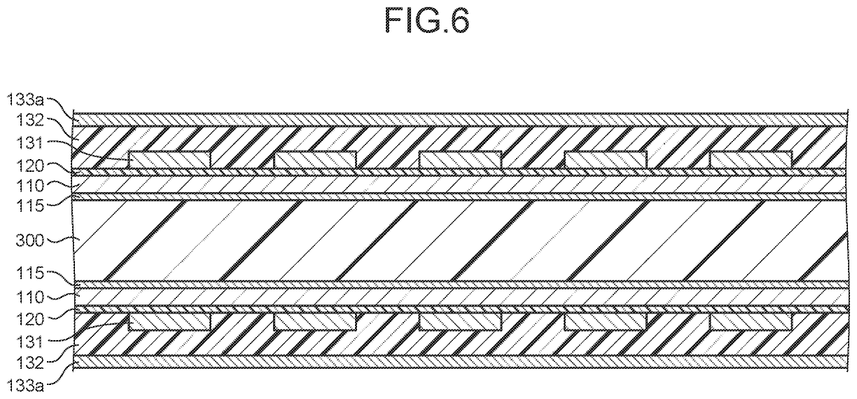

When the wiring layer 131 has been formed, the insulating layer 132 that covers the wiring layer 131 is formed on the resin layer 120 (Step S103), and the metal foil layer 133a is laminated on the insulating layer 132. That is, for example, as illustrated in FIG. 6, the insulating layer 132 that is in an unhardened state and the metal foil layer 133a are laminated in this order on the resin layer 120 so as to cover the wiring layer 131. Then, by heating and hardening the laminated insulating layer 132 that is in the unhardened state while pressurizing the laminated insulating layer 132, the insulating layer 132 and the metal foil layer 133a are brought into close contact with the resin layer 120. FIG. 6 is a diagram illustrating a specific example of an insulating layer forming step.

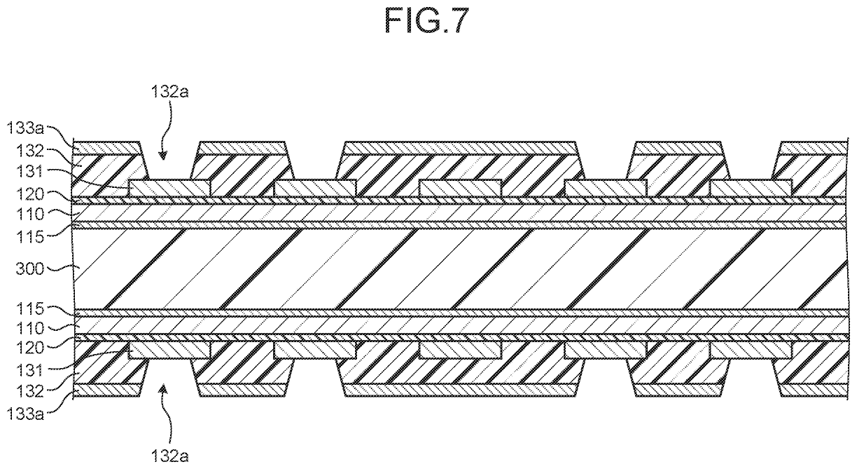

At the position at which each of the vias 141 disposed in the insulating layer 132 and the metal foil layer 133a is formed, an opening portion is formed (Step S104). In other words, for example, as illustrated in FIG. 7, an opening portion 132a that passes through the insulating layer 132 and the metal foil layer 133a and that allows the wiring layer 131 to be exposed from the bottom surface is formed. FIG. 7 is a diagram illustrating a specific example of an opening portion forming step. The opening portion 132a is formed by performing laser beam machining using, for example, a CO₂ laser, an UV laser, or the like.

When the opening portion 132a is formed in the insulating layer 132 and the metal foil layer 133a, a desmear process is performed in order to remove a resin residue. In other words, for example, the resin residue remaining inside the opening portion 132a and the surrounding area is removed by using a potassium permanganate solution.

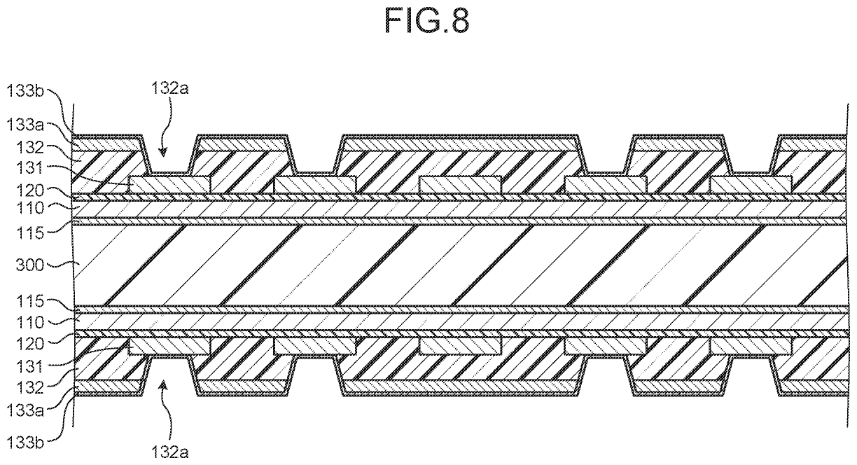

Then, when the opening portion 132a has been formed, the seed layer 133b is formed on the metal foil layer 133a (Step S105). Specifically, for example, as illustrated in FIG. 8, by performing electroless copper plating on the upper surface of the metal foil layer 133a, the seed layer 133b is formed. FIG. 8 is a diagram illustrating a specific example of a seed layer forming step. The seed layer 133b is continuously formed on the upper surface of the metal foil layer 133a, the inner wall surface of the opening portion 132a, and the upper surface of the wiring layer 131 that is exposed on the bottom surface of the opening portion 132a.

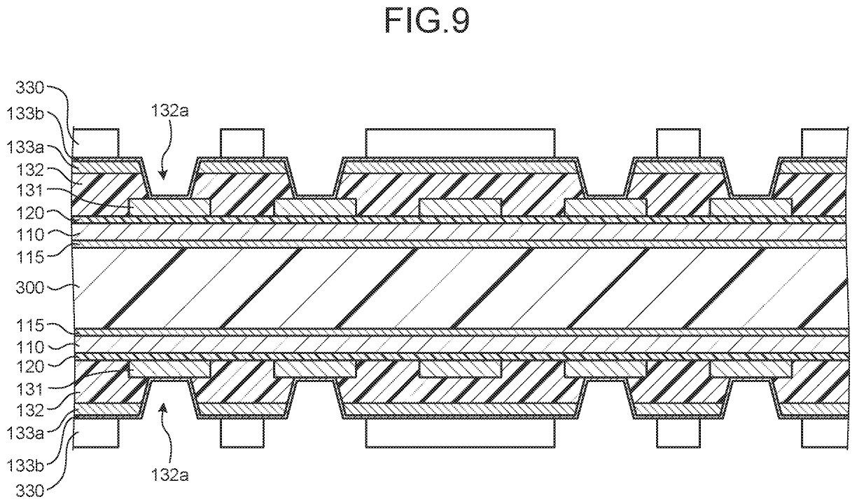

When the seed layer 133b has been formed, a resist layer functioning as a masking material of the electrolytic plating is formed on the seed layer 133b (Step S106). In other words, the resist layer is laminated on the seed layer 133b, and a process of exposure and image development is performed in accordance with the position of the wiring layer 133, so that, for example, as illustrated in FIG. 9, a resist layer 330 is formed on the seed layer 133b at a portion other than the position at which the wiring layer 133 is formed. FIG. 9 is a diagram illustrating a specific example of a resist layer forming step.

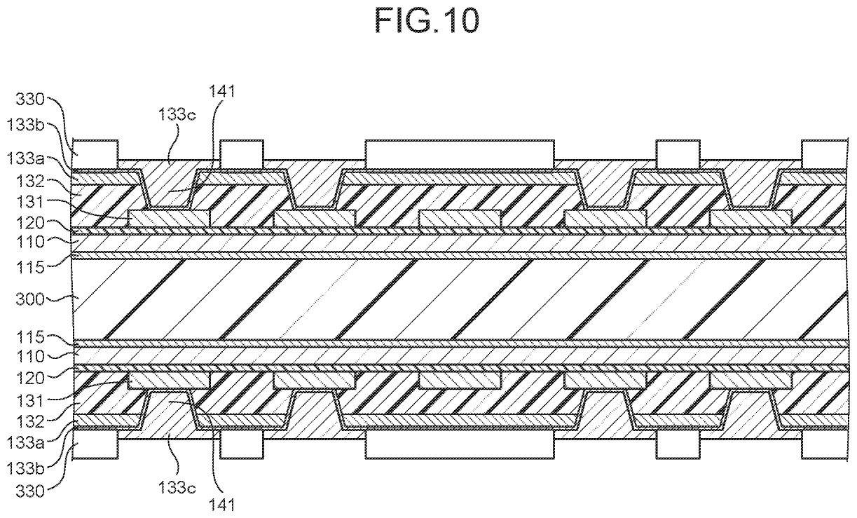

Then, by performing electrolytic plating using the seed layer 133b as a power supply layer, the electrolytic plating layer 133c is formed on the seed layer 133b (Step S107). Specifically, for example, by performing electrolytic copper plating using a copper sulfate plating solution, copper is deposited to the portion in which the resist layer 330 is not formed, and, for example, as illustrated in FIG. 10, the electrolytic plating layer 133c is formed on the seed layer 133b. At this time, each of the vias 141 is formed as a result of electrolytic plating being filled into the opening portion 132a. FIG. 10 is a diagram illustrating a specific example of an electrolytic plating step.

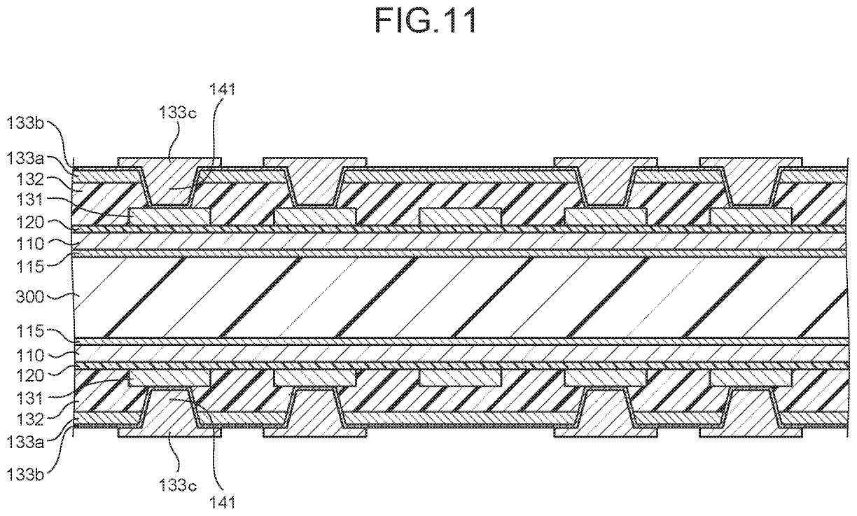

When the electrolytic plating layer 133c has been formed, the resist layer 330 is removed (Step S108). To remove the resist layer 330, for example, sodium hydroxide or an amine-based alkaline stripping solution is used. By removing the resist layer 330, for example, as illustrated in FIG. 11, the electrolytic plating layer 133c protrudes from the insulating layer 132 and the metal foil layer 133a, and enters the state in which the electrolytic plating layer 133c is connected to the wiring layer 131 by way of the seed layer 133b. FIG. 11 is a diagram illustrating a specific example of a resist layer removal step. In the state illustrated in FIG. 11, the seed layer 133b and the metal foil layer 133a remain between the electrolytic plating layer 133c and another electrolytic plating layer, and the electrolytic plating layer 133c makes a short circuit with the other electrolytic plating layer; therefore, there is a need to remove the seed layer 133b and the metal foil layer 133a corresponding to a portion that is associated with the unneeded portion and that does not overlap with the electrolytic plating layer 133c.

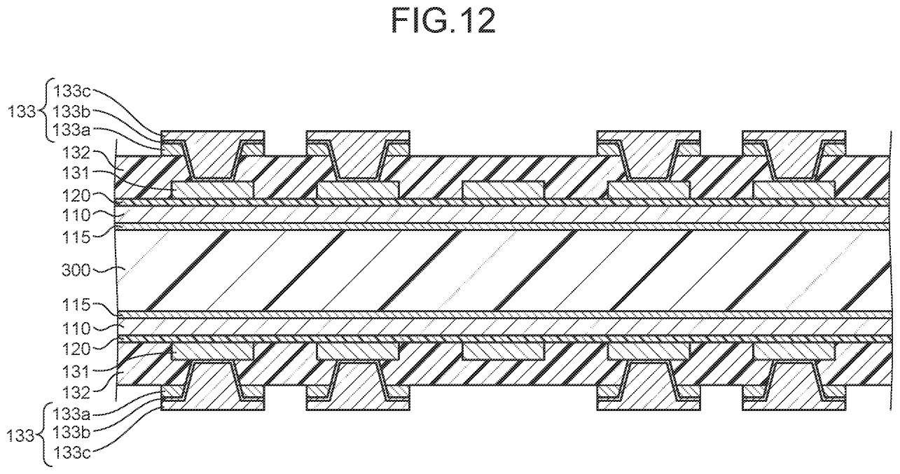

Thus, an etching process is performed on the seed layer 133b and the metal foil layer 133a by using the electrolytic plating layer 133c as a mask (Step S109). Specifically, the seed layer 133b that is formed on the metal foil layer 133a is immersed in an etching solution that selectively dissolve, for example, copper and then, for example, as illustrated in FIG. 12, the seed layer 133b and the metal foil layer 133a corresponding to a portion that is associated with the unneeded portion and that does not overlap with the electrolytic plating layer 133c are removed. As a result of this, the wiring layer 133 constituted by the metal foil layer 133a, the seed layer 133b, and the electrolytic plating layer 133c is formed on the insulating layer 132. FIG. 12 is a diagram illustrating a specific example of an etching step.

When the wiring layer 133 has been formed, the solder resist layer 134 is formed on the insulating layer 132 such that the solder resist layer 134 covers the wiring layer 133 (Step S110), so that the wiring structure 130 has been completed. That is, for example, the wiring layer 133 formed on the insulating layer 132 is covered by the solder resist layer 134.

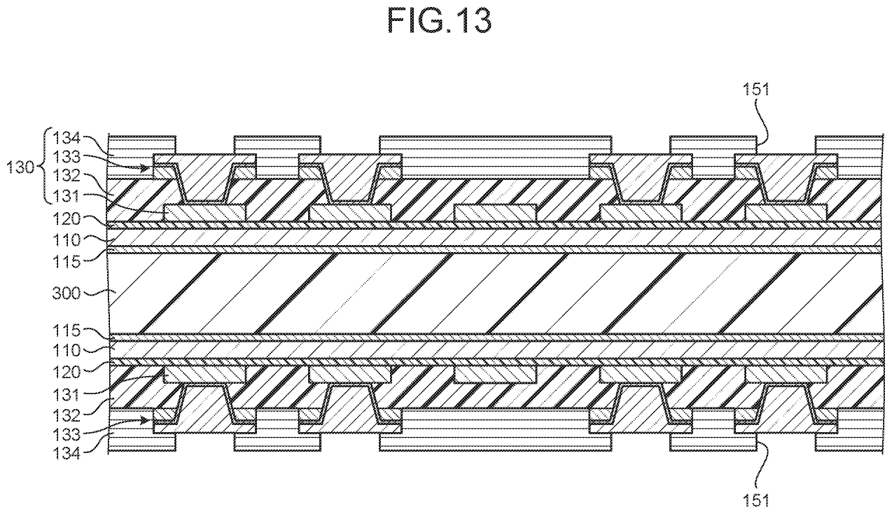

Then, for example, as illustrated in FIG. 13, in the solder resist layer 134, the opening portion 151 that allows the upper surface of the wiring layer 133 to be exposed is formed. FIG. 13 is a diagram illustrating a specific example of a solder resist layer forming step. The electrodes of the semiconductor chip can be mechanically and electrically connected to the wiring layer 133 that is exposed from the opening portion 151. In the case where a photosensitive resin is used as the solder resist layer 134, it is possible to form the opening portion 151 by performing a process of exposure and image development. Furthermore, in the case where a non-photosensitive resin is used as the solder resist layer 134, it is possible to form the opening portion 151 by performing a process of laser beam machining.

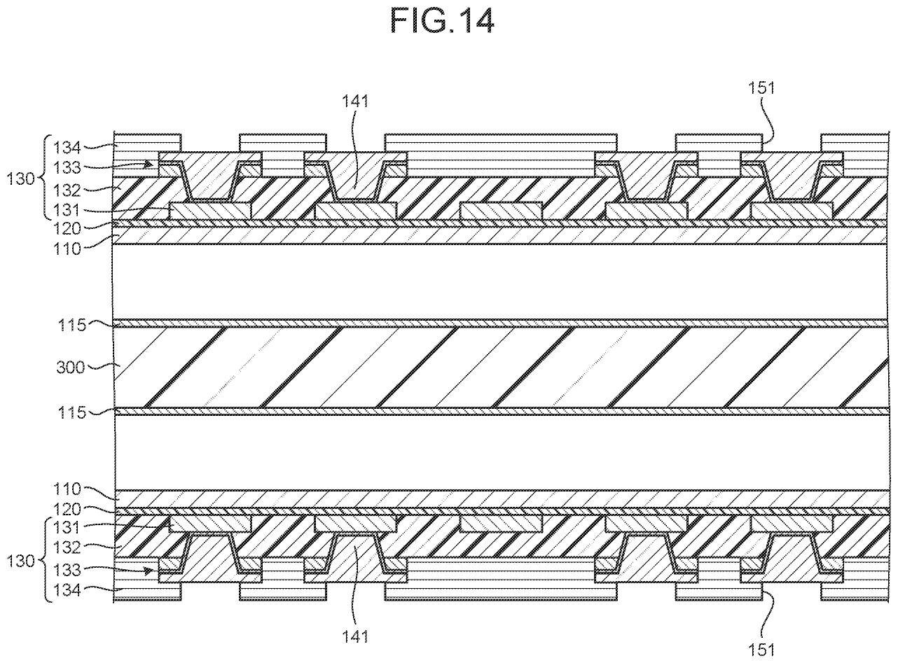

Up to the steps described above, for example, as illustrated in FIG. 13, an intermediate structure in which the metal layer 110 the resin layer 120, and the wiring structure 130 are formed on each of the upper surface and the lower surface of the supporting body 300 is formed. The metal layers 110, the resin layers 120, and the wiring structures 130 constitute the wiring substrate 100. Thus, the metal layers 110, the resin layers 120, and the wiring structures 130 are separated from the intermediate structure (Step S111), so that the wiring substrate 100 is obtained. Specifically, for example, as illustrated in FIG. 14, the layers that are located an upper layer of the metal layer 110 are stripped from the foundation layer 115 of the intermediate structure, so that the metal layer 110 is left on the surface (lower surface) that is located on a side opposite to the surface on which the wiring structure 130 of the resin layer 120 is formed. As a result of this, the wiring substrate 100 that includes the metal layer 110, the resin layer 120, and the wiring structure 130 has been completed. FIG. 14 is a diagram illustrating a specific example of the separated wiring substrate 100. In the separated wiring substrate 100, the metal layer 110 remains on the lower surface of the resin layer 120, stiffness of the wiring substrate 100 is ensured. As a result of this, it is possible to suppress deformation of the wiring substrate 100 in the course of manufacturing the semiconductor device using the wiring substrate 100, and it is thus possible to improve handling of the wiring substrate 100.

Furthermore, in the method of manufacturing the wiring substrate 100 illustrated in FIG. 3, it may be possible to repeat the same processes performed at Step S103 to Step S109 at the step between Step S109 and Step S110, and laminate a plurality of insulating layers and a plurality of wiring layers.

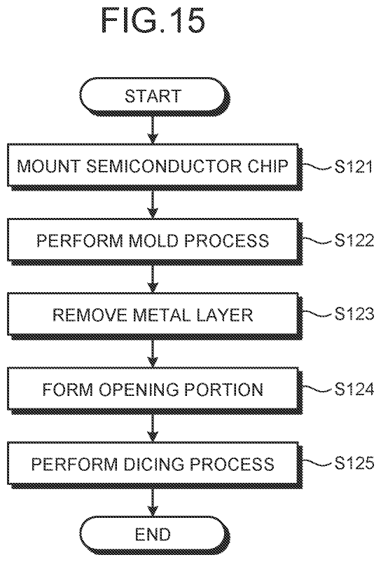

In the following, a method of manufacturing a semiconductor device constituted by the wiring substrate 100 will be specifically described with reference to FIG. 15. FIG. 15 is a flowchart illustrating one example of the flow of the method of manufacturing the semiconductor device according to the embodiment.

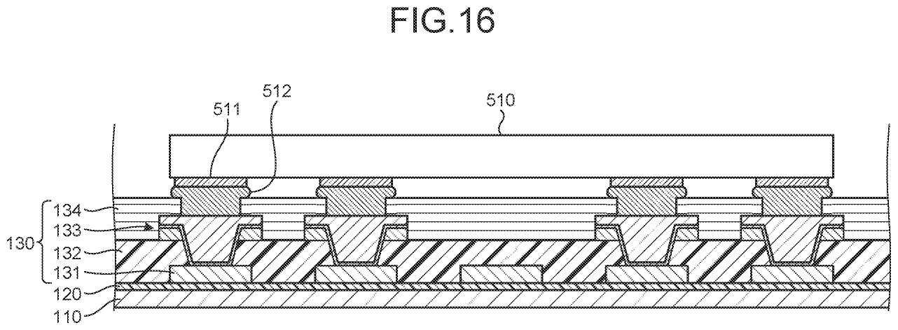

First, a semiconductor chip is mounted on the wiring structure 130 of the wiring substrate 100 (Step S121), and the wiring layer 133 that is exposed from the opening portion 151 disposed in the solder resist layer 134 and the electrodes of the semiconductor chip are mechanically and electrically connected. FIG. 16 is a diagram illustrating a specific example of a semiconductor chip mounting step. Specifically, for example, as illustrated in FIG. 16, a semiconductor chip 510 is mounted above the solder resist layer 134, each of electrodes 511 of the semiconductor chip 510 is bonded to the wiring layer 133 by, for example, solder 512.

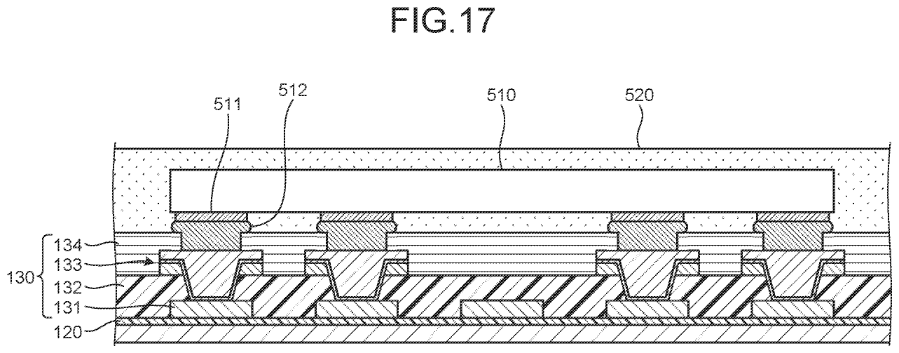

Then, a mold process of encapsulating the semiconductor chip 510 mounted on the wiring substrate 100 is performed by using, for example, a encapsulating resin, such as an epoxy resin (Step S122). Specifically, the wiring substrate 100 on which the semiconductor chip 510 has been mounted is accommodated in a metal mold, and a fluidized encapsulating resin is injected into the metal mold. Then, as a result of the encapsulating resin being heated to a predetermined temperature and hardened, for example, as illustrated in FIG. 17, a encapsulating resin 520 is filled in a space around the semiconductor chip 510, and the encapsulating resin 520 that encapsulates the semiconductor chip 510 mounted on the wiring substrate 100 is formed. FIG. 17 is a diagram illustrating a specific example of a mold step.

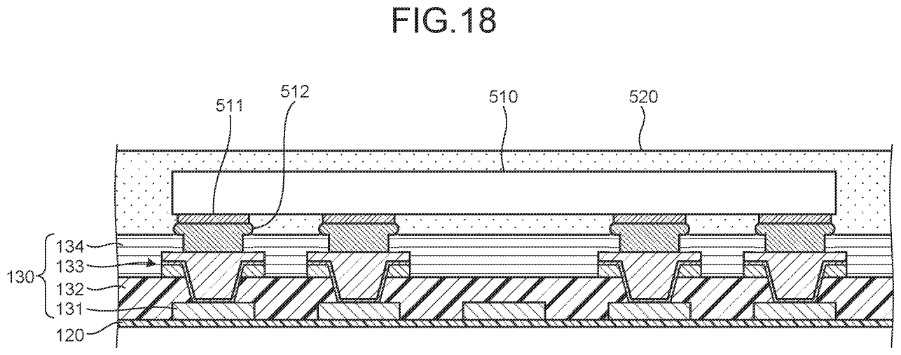

When the semiconductor chip 510 mounted on the wiring substrate 100 has been encapsulated by the encapsulating resin 520, the metal layer 110 remaining on the lower surface of the resin layer 120 is removed (Step S123). Specifically, by performing an etching process by using an etching solution, for example, as illustrated in FIG. 18, the metal layer 110 is removed, the lower surface of the resin layer 120 is exposed. FIG. 18 is a diagram illustrating a specific example of a metal layer removal step. To remove the metal layer 110 made of copper, a copper alloy, or the like, an etching solution, such as hydrogen peroxide/aqueous solution of sulfuric acid system, sodium persulfate, or an ammonium persulfate solution, is used.

In the etching process of removing the metal layer 110, the lower surface of the resin layer 120 is exposed in accordance with the dissolution of the metal layer 110, and the etching solution reaches the exposed lower surface of the resin layer 120. However, the resin layer 120 is formed by using the insulating resin having etching resistance with respect to the etching solution that is used to remove the metal layer 110, so that an etching solution is prevented from entering the layers that are disposed on the upper side than the resin layer 120. In other words, the wiring layer 131 that is the lowermost layer and that is located by brought into contact with the resin layer 120 is protected from the etching solution by the resin layer 120, the etching solution does not dissolve the wiring layer 131. As a result, it is possible to suppress damage of the wiring layer 131 caused by the etching solution, and it is thus possible to suppress damage of the wiring structure 130 due to the removal of the metal layer 110.

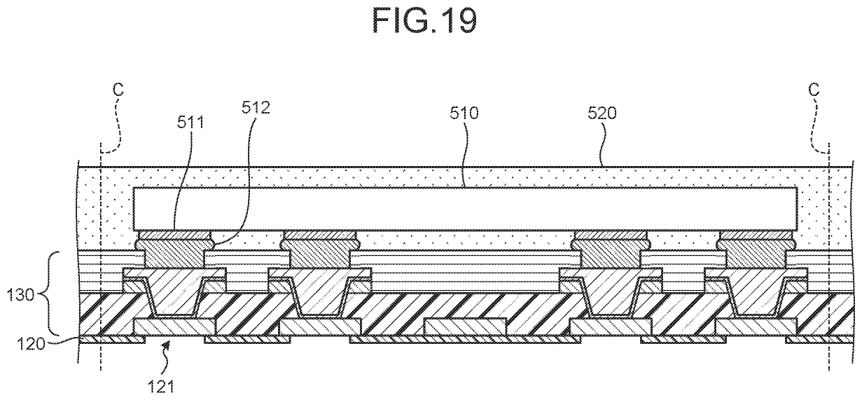

When the metal layer 110 has been removed and the resin layer 120 is exposed, an opening portion is formed in the resin layer 120 (Step S124). The resin layer 120 side of the wiring substrate 100 is the surface to which an external component, an external device, and the like are connected. Accordingly, at the location at which an external connection terminal that is electrically connected to the external component and the external device, for example, as illustrated in FIG. 19, an opening portion 121 of the resin layer 120 is formed, and the wiring layer 131 that is the lowermost layer constituting the wiring structure 130 is exposed from the opening portion 121. FIG. 19 is a diagram illustrating a specific example of an opening portion forming step. At the opening portion 121, for example, an external connection terminal, such as a solder ball, may be formed. In the case where the resin layer 120 is formed by using a non-photosensitive thermosetting resin, it is possible to form the opening portion 121 by performing a process of laser beam machining.

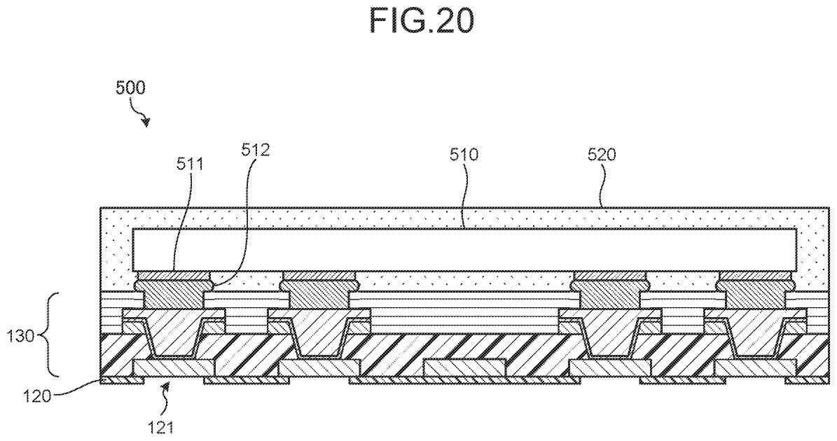

When the opening portion 121 is formed in the resin layer 120, at each of the positions of broken lines C illustrated in FIG. 19, the encapsulating resin 520 and the wiring substrate 100 are cut. As a result of this, the semiconductor device is diced (Step S125), and, for example, as illustrated in FIG. 20, a semiconductor device 500 using the wiring substrate 100 has been completed. In the semiconductor device 500 formed in this way, the wiring layer 131 corresponding to the lowermost layer constituting the wiring structure 130 is exposed from the opening portion 121 that is disposed in the resin layer 120, and becomes a pad in which the external connection terminal is formed. FIG. 20 is a diagram illustrating the structure of the semiconductor device 500.

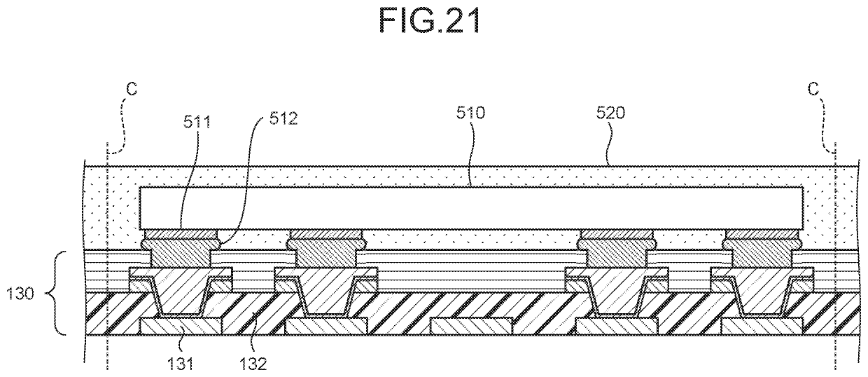

Furthermore, in the method of manufacturing the semiconductor device illustrated in FIG. 15, a case has been described as an example in which, after the metal layer 110 has been removed and the resin layer 120 is exposed, the opening portion 121 is formed in the resin layer 120 (Step S124), but the disclosed technology is not limited to this. For example, instead of a process of forming the opening portion 121 in the resin layer 120 performed at Step S124, it may be possible to remove the resin layer 120 from the wiring substrate 100. Specifically, for example, by irradiating the entirety of the resin layer 120 with an excimer laser, for example, as illustrated in FIG. 21, the resin layer 120 is removed, and, the lower surface of the insulating layer 132 and the lower surface of the wiring layer 131 are exposed on the lower surface of the wiring structure 130. FIG. 21 is a diagram illustrating a specific example of a resin layer removal step.

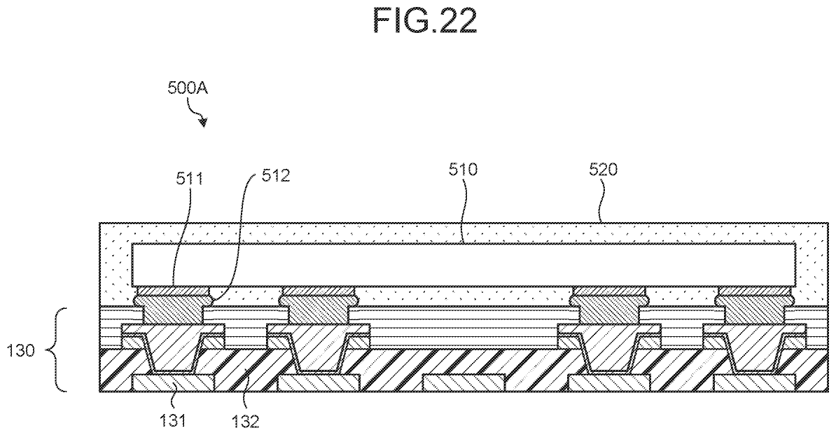

When the resin layer 120 has been removed, at the positions of the broken lines C illustrated in FIG. 21, the encapsulating resin 520 and the wiring substrate 100 are cut. As a result of this, the semiconductor device is diced, and, for example, as illustrated in FIG. 22, a semiconductor device 500A using the wiring substrate 100 has been completed. On the lower surface of the semiconductor device 500A, the wiring layer 131 corresponding to the lowermost layer of the wiring structure 130 is exposed, and functions as an external connection terminal. FIG. 22 is a diagram illustrating the structure of the semiconductor device 500A.

As described above, the wiring substrate (for example, the wiring substrate 100) according to the embodiment includes a metal layer (for example, the metal layer 110), a resin layer (for example, the resin layer 120), and a wiring structure (for example, the wiring structure 130). The resin layer is laminated on the metal layer, and is made of an insulating resin having etching resistance with respect to an etching solution that is used to remove the metal layer. The wiring structure includes a wiring layer (for example, the wiring layer 131) and an insulating layer (for example, the insulating layer 132) that are laminated on the resin layer, and in which the wiring layer is located by being brought into contact with the resin layer. As a result of this, with the wiring substrate according to the embodiment, it is possible to suppress damage caused by removal of the metal layer.

According to an aspect of an embodiment of the wiring substrate disclosed in the present application, an advantage is provided in that it is possible to suppress damage caused by removal of the metal layer.

All examples and conditional language recited herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although the embodiment of the present invention has been described in detail, it should be understood that the various changes, substitutions, and alterations could be made hereto without departing from the spirit and scope of the invention.

Note

(1) A method of manufacturing a wiring substrate comprising:
laminating, on a supporting body, a metal foil with resin that includes
   a foundation layer,
   a metal layer that is pasted in a strippable manner on the foundation layer, and
   a resin layer that is laminated on the metal layer;
forming, by laminating a wiring layer and an insulating layer on the resin layer on the supporting body, a wiring structure in which the wiring layer is located by being brought into contact with the resin layer; and
leaving, by stripping the metal layer from the foundation layer, the metal layer on a surface of the resin layer that is located on a side opposite to a surface of the resin layer on which the wiring structure is formed.
   (2) A method of manufacturing the wiring substrate according to the note (1), wherein the resin layer is made of an insulating resin having etching resistance with respect to an etching solution that is used to remove the metal layer.
   (3) A method of manufacturing a semiconductor device comprising:
mounting a semiconductor chip on the wiring structure included in the wiring substrate that is manufactured by using the method of manufacturing the wiring substrate according to claim 6;
encapsulating the semiconductor chip by a encapsulating resin;
removing the metal layer by etching; and
forming, in the resin layer from which the metal layer has been removed, an opening portion that penetrates up to the wiring layer that is located on a lower surface of the wiring structure.

What is claimed is:

1. A wiring substrate comprising:
a metal layer;
a resin layer that is laminated on the metal layer; and
a wiring structure that includes a wiring layer and an insulating layer that are laminated on the resin layer, and in which the wiring layer is located by being brought into contact with the resin layer.

2. The wiring substrate according to claim 1, wherein the resin layer is made of an insulating resin having etching resistance with respect to an etching solution that is used to remove the metal layer.

3. The wiring substrate according to claim 1, wherein the resin layer is made of an insulating resin that does not include a reinforcement material.

4. The wiring substrate according to claim 1, wherein the resin layer is made of a same insulating resin as an insulating resin that is used for the insulating layer included in the wiring structure.

5. The wiring substrate according to claim 1, wherein the resin layer has a thickness that is thinner than a thickness of the metal layer.

6. The wiring substrate according to claim 1, wherein the resin layer has a thickness that is thinner than a thickness of the wiring layer.

7. The wiring substrate according to claim 1, wherein the resin layer has a thickness that is thinner than a thickness of the insulating layer.
